(19) United States
(12) Patent Application Publication
(10) Pub. No.: US 2021/0153354 A1
(43) Pub. Date: May 20, 2021

(54) INTERPOSER USING INCLINED ELECTRODE AND MANUFACTURING METHOD THEREOF

(71) Applicant: ELECTRONICS AND TELECOMMUNICATIONS RESEARCH INSTITUTE, Daejeon (KR)

(72) Inventors: Dae Seon KIM, Gwangju (KR); Jong Jin LEE, Gwangju (KR)

(21) Appl. No.: 17/068,600

(22) Filed: Oct. 12, 2020

(30) Foreign Application Priority Data
Nov. 19, 2019 (KR) 10-2019-0148505

(51) Int. Cl. H05K 1/18; H01L 23/498

(52) U.S. Cl. CPC H05K 1/181; H05K 2201/10378; H01L 23/49827

(57) ABSTRACT

Provided is an interposer using an inclined electrode and a manufacturing method thereof. The interposer may include a first plate having at least one inclined surface formed between a first layer in which an upper portion is located and a second layer in which a lower portion is located, a second plate having an upper portion formed along the first layer and a lower portion formed to extend along the upper portion of the first plate, at least one inclined surface, and the second layer, and at least one electrode formed along the upper portion of the first plate, at least one inclined surface, and the lower portion of the second plate. In the at least one electrode, a portion formed along the upper portion of the first plate and a portion formed along the lower portion of the second plate may be exposed.

### CROSS-REFERENCE TO RELATED APPLICATION(S)

This application claims the benefit of Korean Patent Application No. 10-2019-0148505, filed on Nov. 19, 2019, in the Korean Intellectual Property Office, the disclosure of which is incorporated herein by reference.

### BACKGROUND

### 1. Field of the Invention

Example embodiments relate to an interposer using an inclined electrode and a manufacturing method thereof.

### 2. Description of the Related Art

In a data center and a communication base station, a high-speed and highly integrated communication system may be required to reduce operating costs such as cooling costs and facility investment. With the high-speed and highly integrated communication system, miniaturization and integration of optical components have shifted from a typical system front panel mounting method to an on-board optical component structure mounted on a system board surface. The miniaturization and integration of optical components based on the on-board optical component structure are improved in a way that increases a density of a system input/output port and improves heat dissipation characteristics.

A typical optical component may employ a method of connecting to a conductive wire on a two-dimensional plane for high-speed signal transmission. However, an electrical connection using a wire may be limited in high-speed signal transmission and unsuitable for the integration and miniaturization. To solve this, leading overseas optical component companies are developing technologies for laminating optical components by applying an interposer equipped with a through-via electrode to a substrate.

The interposer with the through-via electrode may be manufactured using a method of forming through holes on a silicon or glass substrate through semiconductor etching, laser processing, and the like and filling a conductive material therein. In terms of high-frequency characteristics and electrode integration for high-speed signal transmission, it is advantageous as a diameter of the through-via electrode is smaller. However, due to characteristics of through-hole processing, as a thickness of the substrate increases, the diameter of the through-via electrode may be increased. Also, in a process of filling the through-hole with the conductive material through plating and the like, as a depth of the through-hole increases and a diameter of the through-hole decreases, a difficulty in a process of evenly filling a conductive filler material without empty space may increase, which may lead to an increase in manufacturing cost.

### SUMMARY

An aspect provides a technology that forms an electrode connecting an upper portion and a lower portion of a plate through an inclined surface without using a through-via electrode, thereby significantly reducing a difficulty of an interposer manufacturing process which is limited by a diameter and a shape of the through-via electrode based on a thickness of a substrate.

According to an aspect, there is provided an interposer including: a first plate having at least one inclined surface formed between a first layer in which an upper portion is located and a second layer in which a lower portion is located; a second plate having an upper portion formed along the first layer and a lower portion formed to extend along the upper portion of the first plate, the at least one inclined surface, and the second layer; and at least one electrode formed along the upper portion of the first plate, the at least one inclined surface, and the lower portion of the second plate, wherein, in the at least one electrode, a portion formed along the upper portion of the first plate and a portion formed along the lower portion of the second plate are exposed.

The first plate may have a plurality of inclined surfaces formed between the first layer and the second layer, consecutive inclined surfaces of the plurality of inclined surfaces having different inclination directions.

The first plate may have a plurality of inclined surfaces formed between the first layer and the second layer in parallel, the plurality of inclined surfaces having different points at which inclinations start on the upper portion of the first plate.

In the at least one electrode, the portion formed along the upper portion of the first plate and the portion formed along the lower portion of the second plate may have different lengths.

The at least one electrode may be formed in a pattern of a straight line, an oblique line, or a curved line along the upper portion of the first plate, the at least one inclined surface, and the lower portion of the second plate.

According to another aspect, there is provided a method of manufacturing an interposer, the method including: forming at least one inclined surface having a level difference from a first layer to a second layer in an upper portion of a first plate; forming at least one electrode to be consecutively in close contact with a first area of the first plate located on the first layer, the at least one inclined surface, and a second area of the first plate located on the second layer; forming a second plate to contain the upper portion of the first plate and the at least one electrode; polishing an upper portion of the second plate up to the first layer; and polishing a lower portion of the first plate up to the second layer.

The forming of the at least one inclined surface may include forming a plurality of inclined surfaces having level differences from the first layer to the second layer in the upper portion of the first plate, consecutive inclined surfaces of the plurality of inclined surfaces having different inclination directions.

The forming of the at least one inclined surface may include forming a plurality of inclined surfaces having level differences from the first layer to the second layer in the upper portion of the first plate in parallel, the plurality of inclined surfaces having different points at which inclinations start on the upper portion of the first plate.

The forming of the at least one electrode may include forming the at least one electrode such that a portion formed in the first area and a portion formed in the second area have different lengths.

The forming of the at least one electrode may include forming the at least one electrode in a pattern of a straight line, an oblique line, or a curved line in the first area, the at least one inclined surface, and the second area, consecutively.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a perspective view illustrating an interposer according to an example embodiment;

FIG. 2 is a side view illustrating the interposer of FIG. 1;

FIG. 3 is a side view illustrating a first plate of FIG. 1;

FIG. 4 is a side view illustrating a second plate of FIG. 1;

FIG. 5 is a flowchart illustrating a method of manufacturing an interposer;

FIGS. 6 through 11 are diagrams illustrating a method of manufacturing an interposer; and

FIGS. 12 through 17 are diagrams illustrating an interposer according to example embodiments.

### DETAILED DESCRIPTION

Hereinafter, example embodiments will be described in detail with reference to the accompanying drawings. It should be understood, however, that there is no intent to limit this disclosure to the particular example embodiments disclosed. On the contrary, example embodiments are to cover all modifications, equivalents, and alternatives falling within the scope of the example embodiments.

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element.

Unless otherwise defined, all terms, including technical and scientific terms, used herein have the same meaning as commonly understood by one of ordinary skill in the art to which this disclosure pertains. Terms, such as those defined in commonly used dictionaries, are to be interpreted as having a meaning that is consistent with their meaning in the context of the relevant art, and are not to be interpreted in an idealized or overly formal sense unless expressly so defined herein.

Regarding the reference numerals assigned to the elements in the drawings, it should be noted that the same elements will be designated by the same reference numerals, wherever possible, even though they are shown in different drawings. Also, in the description of embodiments, detailed description of well-known related structures or functions will be omitted when it is deemed that such description will cause ambiguous interpretation of the present disclosure.

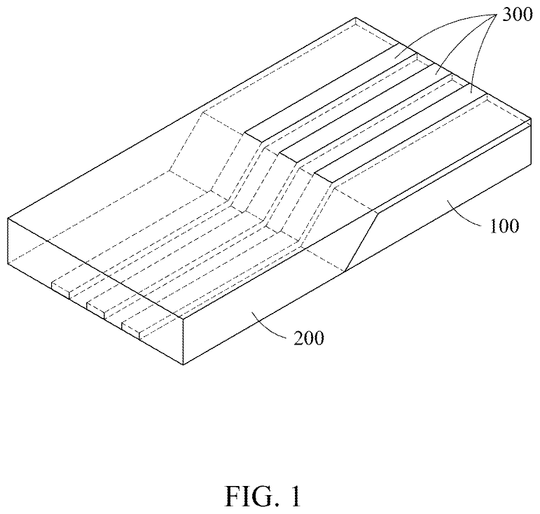

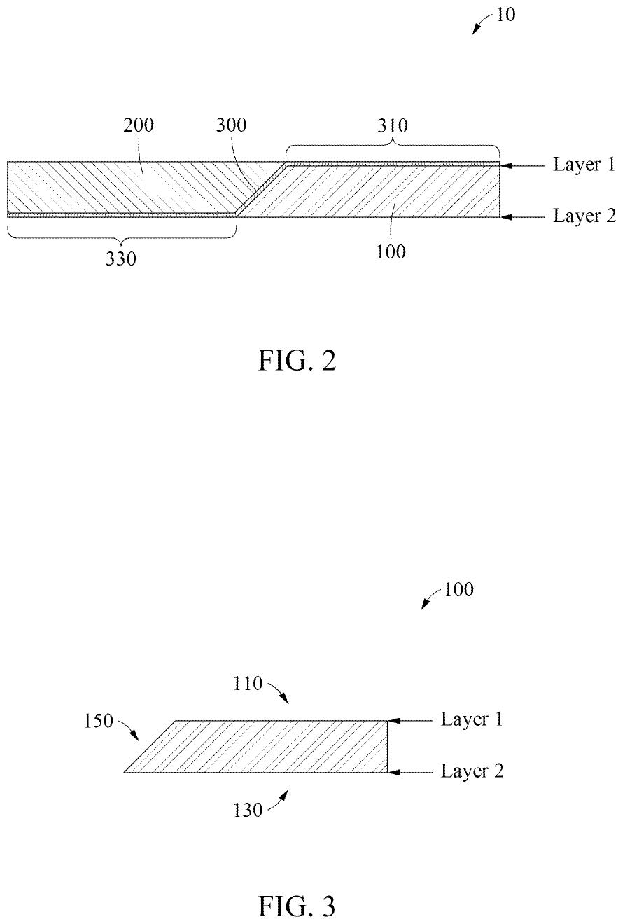

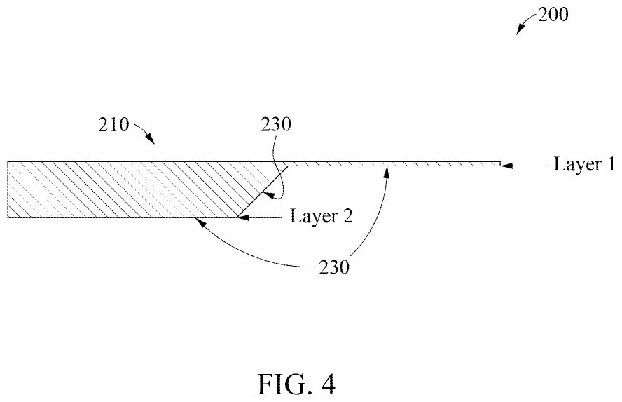

FIG. 1 is a perspective view illustrating an interposer according to an example embodiment, FIG. 2 is a side view illustrating the interposer of FIG. 1, FIG. 3 is a side view illustrating a first plate of FIG. 1, and FIG. 4 is a side view illustrating a second plate of FIG. 1.

An interposer 10 may include a first plate 100, a second plate 200, and at least one electrode 300.

The interposer 10 may electrically connect an upper portion and a lower portion of a substrate through an electrode formed along an inclined surface in the substrate without using a through-via electrode. The interposer 10 may significantly reduce a difficulty of a typical interposer manufacturing process which is limited by a diameter and a shape of a through-via electrode based on a thickness of a substrate.

The first plate 100 may have at least one inclined surface 150 formed between a first layer (hereinafter, also referred to as a “layer 1”) in which an upper portion 110 of the first plate 100 is located and a second layer (hereinafter, also referred to as a “layer 2”) in which a lower portion 130 of the first plate 100 is located. For example, the first plate 100 may be implemented with a silicon wafer, glass, sapphire, ceramic, or the like.

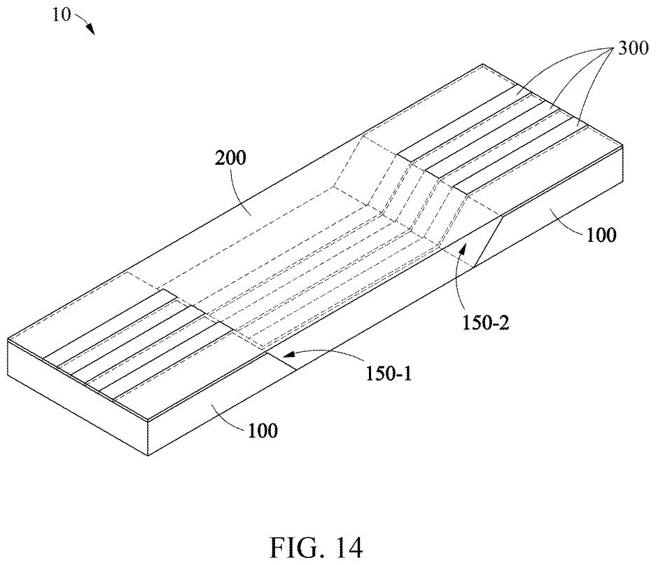

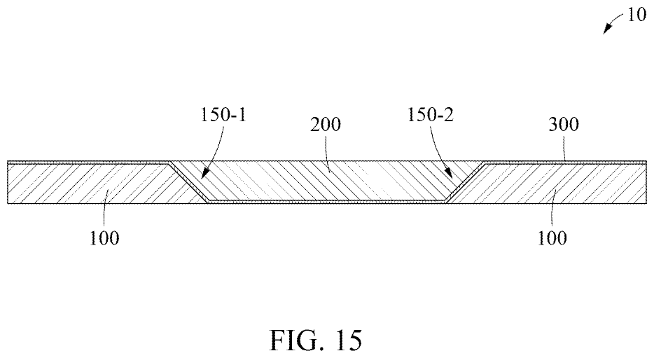

The first plate 100 may have a plurality of inclined surfaces formed between the layer 1 and the layer 2. In this case, consecutive inclined surfaces of the plurality of inclined surfaces may have different inclination directions. Related description will be made in detail with reference to FIGS. 14 and 15.

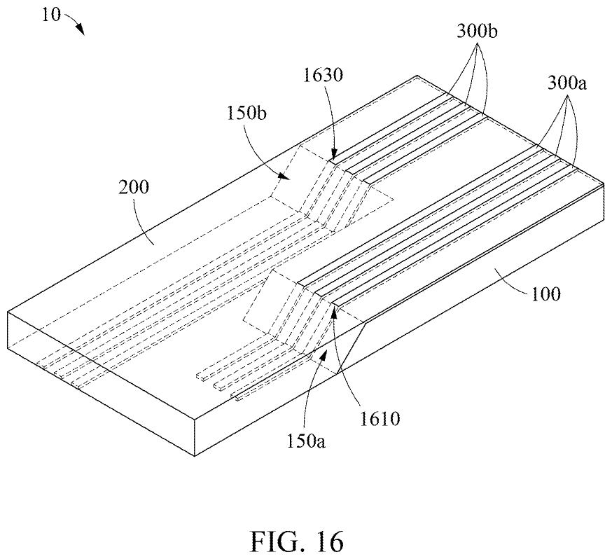

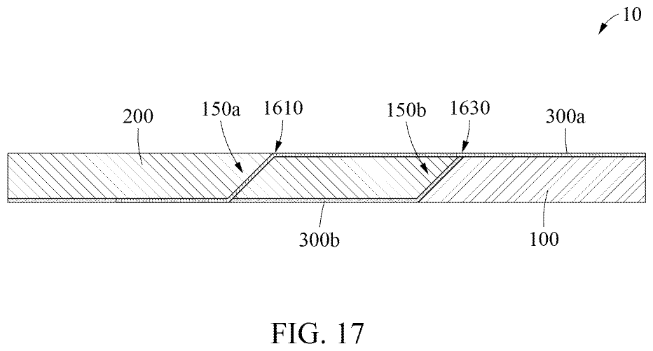

The first plate 100 may have a plurality of inclined surfaces formed in parallel. The plurality of inclined surfaces may have different points at which inclinations start on the upper portion 110 of the first plate 100. Related description will be made in detail with reference to FIGS. 16 and 17.

The second plate 200 may have an upper portion 210 formed along the layer 1. The second plate 200 may have a lower portion 230 formed to extend along the upper portion 110 of the first plate 100, the at least one inclined surface 150, and the layer 2. For example, the second plate 200 may be implemented with a silicon wafer, glass, a curable glass resin, sapphire, ceramic, a ceramic substrate, or the like.

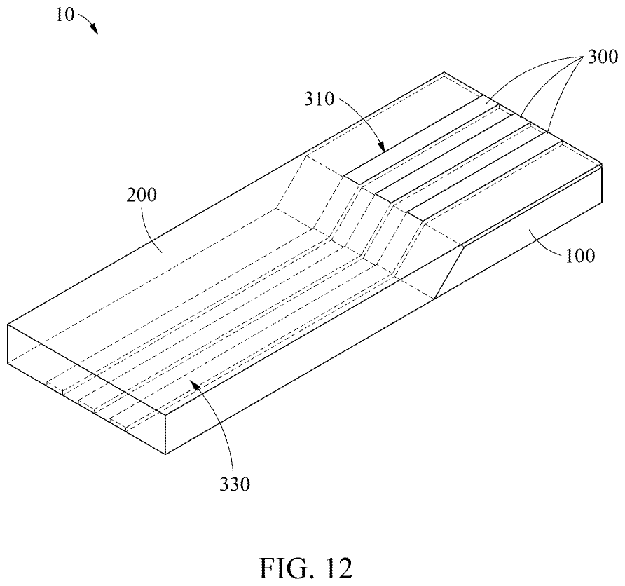

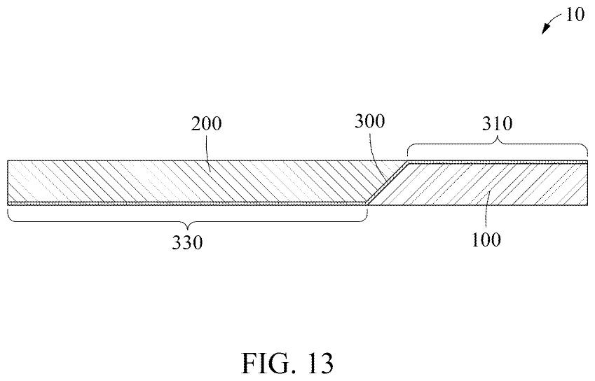

The at least one electrode 300 may be formed along the upper portion 110 of the first plate 100, the at least one inclined surface 150, and the lower portion 230 of the second plate 200. As an example, the at least one electrode 300 may be formed such that a portion 310 formed along the upper portion 110 of the first plate 100 and a portion 330 formed along the lower portion 230 of the second plate 200 have different lengths. Related description will be made in detail with reference to FIGS. 12 and 13. As another example, the at least one electrode 300 may be formed in a pattern of a straight line, an oblique line, or a curved line along the upper portion 110 of the first plate 100, the at least one inclined surface 150, and the lower portion 230 of the second plate 200.

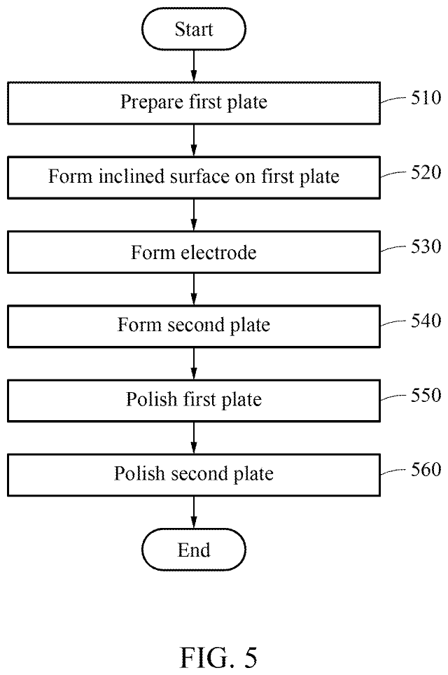

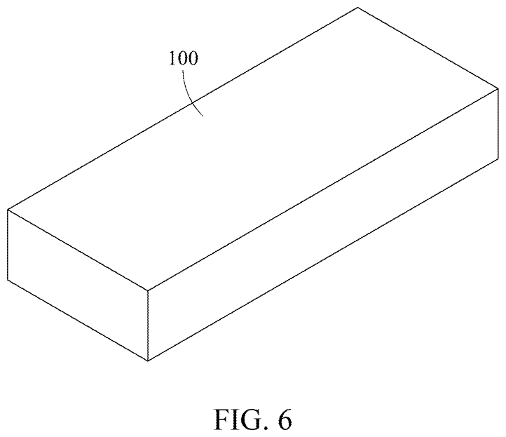

FIG. 5 is a flowchart illustrating a method of manufacturing an interposer and FIGS. 6 through 11 are diagrams illustrating a method of manufacturing an interposer.

Referring to FIG. 6, to manufacture the interposer 10, the first plate 100 may be prepared in operation 510.

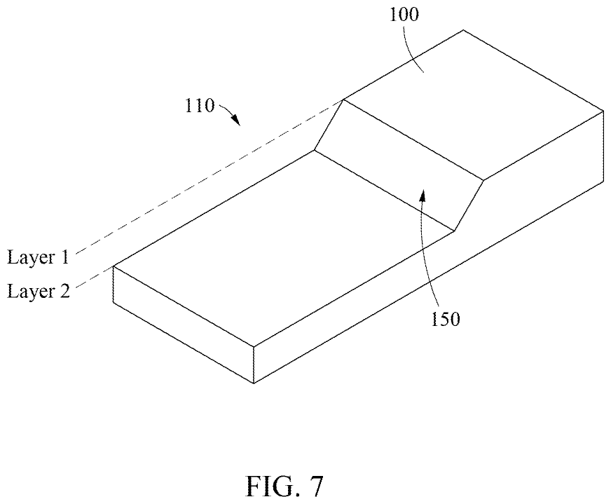

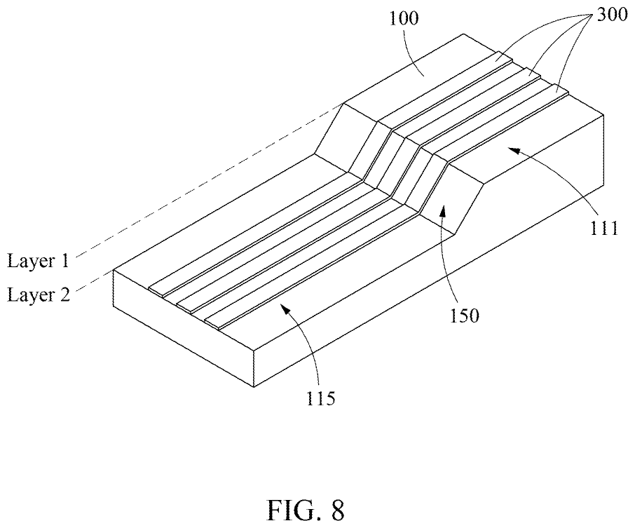

Referring to FIG. 7, the at least one inclined surface 150 may be formed to be having a level difference from the layer 1 to the layer 2 in the upper portion 110 of the first plate 100 in operation 520. As an example, operation 520 may be implemented through a photomask process. In the upper portion 110 of the first plate 100, a plurality of inclined surfaces that has level differences from the layer 1 to the layer 2 and includes consecutive inclined surfaces having different inclination directions may be formed. As another example, a plurality of inclined surfaces having level differences from the layer 1 to the layer 2 may be formed in parallel in the upper portion 110 of the first plate 100. In this example, the plurality of inclined surfaces may have different points at which inclinations start on the upper portion 110 of the first plate 100.

Referring to FIG. 8, in operation 530, the at least one electrode 300 may be formed to be consecutively in close contact with a first area 111 of the first plate 100 located on the layer 1, the at least one inclined surface 150, and a second area 115 of the first plate 100 located on the layer 2. That is, the upper portion 110 of the first plate 100 may be a portion that includes the first area 111, the at least one inclined surface 150, and the second area 115. As an example, operation 530 may be implemented through a photomask process. The at least one electrode 300 may be formed such that a portion formed in the first area 111 and a portion formed in the second area 115 have different lengths. As another example, the at least one electrode 300 may be formed in a pattern of a straight line, an oblique line, or a curved line in the first area 111, the at least one inclined surface 150, and the second area 115, consecutively.

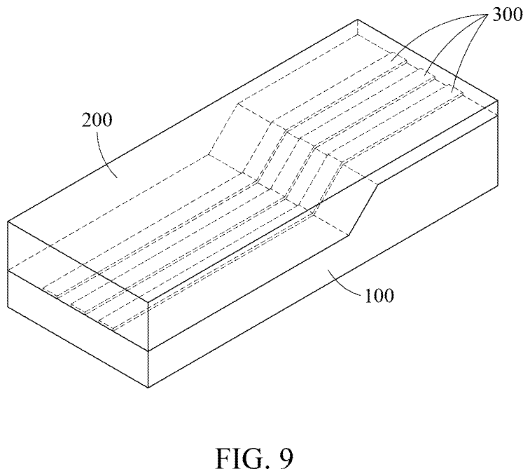

Referring to FIG. 9, in operation 540, the second plate 200 may be formed to contain the upper portion 110 of the first plate 100 and the at least one electrode 300. The second plate 200 may be implemented with, for example, a curable glass resin. That is, the curable glass resin may be applied to the upper portion 110 of the first plate 100 in which the at least one electrode 300 is formed, so that the first plate 100 and the second plate 200 serve as substrates supporting the at least one electrode 300.

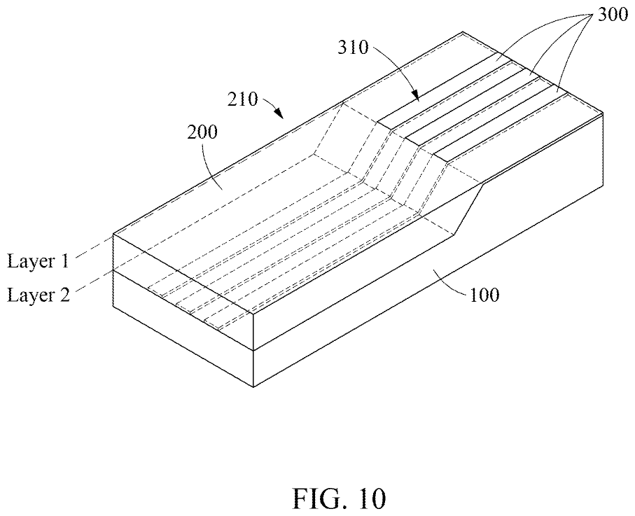

Referring to FIG. 10, the upper portion 210 of the second plate 200 may be polished up to the layer 1 in operation 550. In this example, the portion 310 of the at least one electrode 300 formed along the upper portion 110 of the first plate 100 may be exposed.

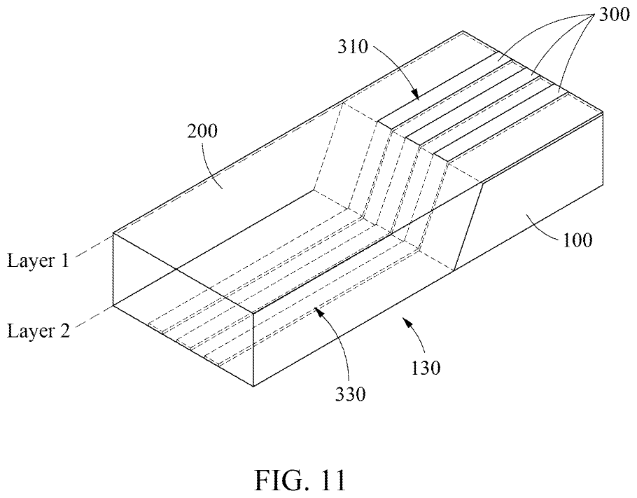

Referring to FIG. 11, the lower portion 130 of the first plate 100 may be polished up to the layer 2 in operation 560. In this example, the portion 330 of the at least one electrode 300 formed along the lower portion 230 of the second plate 200 may be exposed.

In the above-described method of manufacturing the interposer 10, it is possible to improve a through-via electrode structure and a manufacturing method that forms holes through an upper portion and a lower portion of a substrate and fills a conductive material therein. That is, a typical process of manufacturing an interposer using a through-via electrode may require a three-step photomask process including: a) through-hole fabrication (photomask 1); b) through-via electrode filling; c) upper and lower surface polishing; d) upper electrode fabrication (photomask 2); and e) lower electrode fabrication (photomask 3).

In contrast, for example, the interposer 10 may require a two-step photomask process using the manufacturing method through operations 520 and 530. Specifically, operation 520 may be performed through high-temperature molding that enables mass production based on a substrate material, so that the photomask process may be further simplified.

FIGS. 12 through 17 are diagrams illustrating an interposer according to example embodiments.

Referring to FIGS. 12 and 13, an interposer 10 may include at least one electrode 300 formed such that a portion 310 formed along an upper portion 110 of a first plate 100 and a portion 330 formed along a lower portion 230 of a second plate 200 have different lengths.

Referring to FIGS. 14 and 15, the interposer 10 may include a plurality of inclined surfaces 150-1 and 150-2. Among the plurality of inclined surfaces 150-1 and 150-2, consecutive inclined surfaces of the first plate 100 may have different inclination directions.

Referring to FIGS. 16 and 17, in the interposer 10, a plurality of inclined surfaces 150a and 150b having different points 1610 and 1630 at which inclinations start on the upper portion of the first plate 100 may be formed in parallel. The interposer 10 may include a plurality of electrodes 300a and 300b formed along the plurality of inclined surfaces 150a and 150b.

In addition, the interposer 10 may be implemented in a form in which a plurality of interposers 10 are laminated to connect a curved electrode wire structure and a complex wiring structure in a stacked manner. However, embodiments related to the interposer 10 are not limited thereto.

The interposer 10 may reduce a time required for via hole drilling and via-electrode filling based on a thickness of a substrate and improve a physical limitation of a typical microelectrode implementation of a through-via electrode for high-speed signal connection. The interposer 10 may form an inclined surface on a substrate, simultaneously manufacture an electrode of the inclined surface and electrodes of upper and lower surfaces through a two-dimensional semiconductor process, and electrically connect the electrodes, thereby solving the issues of a manufacturing time dependent on the thickness of the substrate and overcoming the physical limitation of the microelectrode implementation.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

What is claimed is:

1. An interposer comprising:
a first plate having at least one inclined surface formed between a first layer in which an upper portion is located and a second layer in which a lower portion is located;
a second plate having an upper portion formed along the first layer and a lower portion formed to extend along the upper portion of the first plate, the at least one inclined surface, and the second layer; and
at least one electrode formed along the upper portion of the first plate, the at least one inclined surface, and the lower portion of the second plate,
wherein, in the at least one electrode, a portion formed along the upper portion of the first plate and a portion formed along the lower portion of the second plate are exposed.

2. The interposer of claim 1, wherein the first plate has a plurality of inclined surfaces formed between the first layer and the second layer, consecutive inclined surfaces of the plurality of inclined surfaces having different inclination directions.

3. The interposer of claim 1, wherein the first plate has a plurality of inclined surfaces formed between the first layer and the second layer in parallel, the plurality of inclined surfaces having different points at which inclinations start on the upper portion of the first plate.

4. The interposer of claim 1, wherein, in the at least one electrode, the portion formed along the upper portion of the first plate and the portion formed along the lower portion of the second plate have different lengths.

5. The interposer of claim 1, wherein the at least one electrode is formed in a pattern of a straight line, an oblique line, or a curved line along the upper portion of the first plate, the at least one inclined surface, and the lower portion of the second plate.

6. A method of manufacturing an interposer, the method comprising:
forming at least one inclined surface having a level difference from a first layer to a second layer in an upper portion of a first plate;
forming at least one electrode to be consecutively in close contact with a first area of the first plate located on the first layer, the at least one inclined surface, and a second area of the first plate located on the second layer;
forming a second plate to contain the upper portion of the first plate and the at least one electrode;
polishing an upper portion of the second plate up to the first layer; and
polishing a lower portion of the first plate up to the second layer.

7. The method of claim 6, wherein the forming of the at least one inclined surface comprises:
forming a plurality of inclined surfaces having level differences from the first layer to the second layer in the upper portion of the first plate, consecutive inclined surfaces of the plurality of inclined surfaces having different inclination directions.

8. The method of claim 6, wherein the forming of the at least one inclined surface comprises:
forming a plurality of inclined surfaces having level differences from the first layer to the second layer in the upper portion of the first plate in parallel, the plurality of inclined surfaces having different points at which inclinations start on the upper portion of the first plate.

9. The method of claim 6, wherein the forming of the at least one electrode comprises:
forming the at least one electrode such that a portion formed in the first area and a portion formed in the second area have different lengths.

10. The method of claim 9, wherein the forming of the at least one electrode comprises:
forming the at least one electrode in a pattern of a straight line, an oblique line, or a curved line in the first area, the at least one inclined surface, and the second area, consecutively.
